(19) United States
(12) Patent Application Publication
(10) Pub. No.: US 2025/0248126 A1
(43) Pub. Date: Jul. 31, 2025

(54) THREE DIMENSIONAL SEMICONDUCTOR STRUCTURE AND MANUFACTURING METHOD THEREOF

(71) Applicant: NANYA TECHNOLOGY CORPORATION, New Taipei city (TW)

(72) Inventor: Sheng-Fu HUANG, New Taipei City (TW)

(21) Appl. No.: 18/423,827

(22) Filed: Jan. 26, 2024

(51) Int. Cl. H01L 27/06; H01L 21/822; H01L 23/00; H01L 23/367; H01L 25/065

(52) U.S. Cl. CPC H10D 88/00; H01L 23/367; H01L 24/11; H01L 24/16; H01L 25/0657; H10D 84/038; H10D 88/01; H01L 2224/11; H01L 2224/16148; H01L 2224/16238; H01L 2225/06513; H01L 2924/1515

(57) ABSTRACT

A three dimensional semiconductor structure manufacturing method includes the following steps, providing a wafer, and the wafer includes a front side and a back side. A front side of the wafer is adhered to a supporting substrate, a photoresist layer is coated on the back side of the wafer, and the back side of the wafer is etched to form a plurality of grooves on the back side of the wafer. The wafer is diced to form a plurality of semiconductor devices.

### BACKGROUND

### Technical Field

The present disclosure relates to a semiconductor structure and manufacturing method thereof. More particularly, the present disclosure relates to a three dimensional semiconductor structure and manufacturing method thereof.

### Description of Related Art

With the rapid growth of electronic industry, the development of integrated circuits (ICs) has achieved high performance and miniaturization. Technological advances in IC materials and design have produced generations of ICs where each generation has smaller and more complex circuits than the previous generation.

As the number of electronic devices on single chips rapidly increases, three-dimensional (3D) integrated circuit layouts, or stacked chip designs, have been utilized for certain semiconductor devices in an effort to overcome the feature size and density limitations associated with 2D layouts. Generally, in a 3D IC design, two or more semiconductor chips are bonded together, and electrical connections are formed between the semiconductor chips. When facilitating the chip-to-chip electrical connections, the semiconductor devices are stacked together to form the three dimensional semiconductor structure.

However, when the three dimensional semiconductor structure is working, the three dimensional semiconductor structure may accumulate the heat. Therefore, there is a need to increase the heat dissipation efficiency of the three dimensional semiconductor structure so as to improve the working efficiency and service life of the three dimensional semiconductor structure.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide a three dimensional semiconductor structure able to increase the heat dissipation efficiency of the three dimensional semiconductor structure so as to improve the working efficiency and service life of the three dimensional semiconductor structure.

To achieve these and other advantages and in accordance with the objective of the embodiments of the present invention, as the embodiment broadly describes herein, the embodiments of the present invention provides a three dimensional semiconductor structure manufacturing method. The three dimensional semiconductor structure manufacturing method includes the following steps of providing a wafer and the wafer comprises a front side and a back side, adhering the front side of the wafer on a supporting substrate, coating a photoresist layer on the back side of the wafer, etching the back side of the wafer to form a plurality of grooves on the back side of the wafer and dicing the wafer to form a plurality of semiconductor devices.

In some embodiments, each semiconductor device includes a plurality of cooling grooves formed by the grooves on the back side of the wafer.

In some embodiments, the cooling grooves pass horizontally through the semiconductor devices.

In some embodiments, the three dimensional semiconductor structure manufacturing method further includes a step of soldering a first semiconductor device of the semiconductor devices on an interposer, and the cooling grooves face the interposer.

In some embodiments, the three dimensional semiconductor structure manufacturing method further includes a step of soldering a second semiconductor device on the first semiconductor device, and cooling grooves of the second semiconductor device face the first semiconductor device.

In some embodiments, the interposer includes a front side and a back side, and the first semiconductor device is soldered on the front side of the interposer.

In some embodiments, the front side of the interposer includes a plurality of grooves facing the first semiconductor device.

In some embodiments, the grooves of the front side of the interposer pass horizontally through the interposer.

In some embodiments, the back side of the interposer includes a plurality of grooves.

In some embodiments, the grooves of the back side of the interposer pass horizontally through the interposer.

According to another aspect of the present invention, the present invention provides a three dimensional semiconductor structure including a first semiconductor device and a plurality of grooves. The first semiconductor device includes a front side and a back side and the grooves are formed on the back side of the first semiconductor device to form a plurality of cooling grooves.

In some embodiments, the cooling grooves pass horizontally through the first semiconductor devices.

In some embodiments, the three dimensional semiconductor structure further includes an interposer and the first semiconductor device is soldered on the interposer and the cooling grooves face the interposer.

In some embodiments, the three dimensional semiconductor structure further includes a second semiconductor device soldering on the first semiconductor device, and cooling grooves of the second semiconductor device face the first semiconductor device.

In some embodiments, the interposer includes a front side and a back side, and the first semiconductor device is soldered on the front side of the interposer.

In some embodiments, the front side of the interposer includes a plurality of grooves facing the first semiconductor device.

In some embodiments, the grooves of the front side of the interposer pass horizontally through the interposer.

In some embodiments, the back side of the interposer includes a plurality of grooves.

In some embodiments, the grooves of the back side of the interposer pass horizontally through the interposer.

In some embodiments, the first semiconductor device includes a first dielectric layer, a first semiconductor layer, a second dielectric layer, a plurality of metal conductive connections, a plurality of first microbumps and a plurality of second microbumps. The first semiconductor layer is formed on the first dielectric layer, the second dielectric layer is formed on the first semiconductor layer, the metal conductive connections are formed in the first dielectric layer, the first semiconductor layer and the second dielectric layer, the first microbumps are formed on a surface of the first dielectric layer and electrically connecting to the metal conductive connections, and the second microbumps are formed on a surface of the second dielectric layer and electrically connecting to the metal conductive connections.

Hence, the three dimensional semiconductor structure of the present invention includes the grooves formed on the surface of the semiconductor devices to form the cooling grooves so as to increase the porosity of the wafer, allow airflow to circulate therein and increase the heat dissipation efficiency while the semiconductor devices are working. In addition, the cooling grooves may also be formed on the front side and/or the back side of the interposer to increase the heat dissipation efficiency of the semiconductor devices and the interposer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-7 are cross-sectional views of a three dimensional semiconductor structure manufacturing method at various stages in accordance with some embodiments of the present disclosure;

FIG. 8 is a cross-sectional view of a three dimensional semiconductor structure in accordance with another embodiment of the present disclosure; and

FIG. 9 is a flow chart of a three dimensional semiconductor structure manufacturing method in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

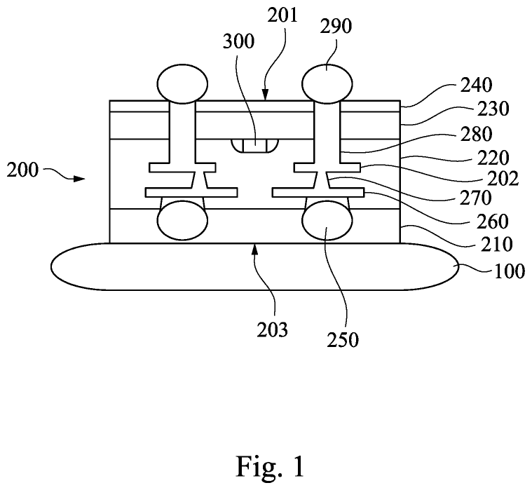

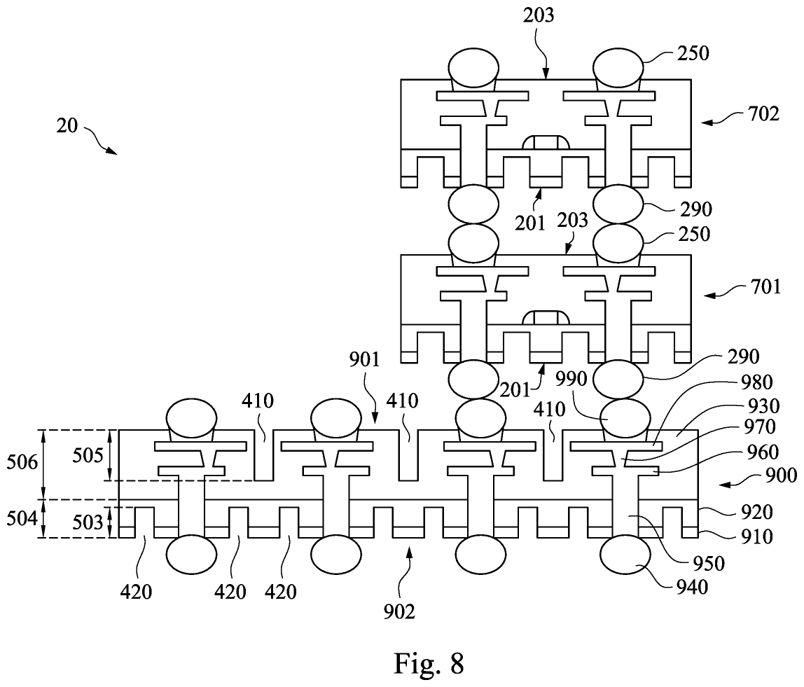

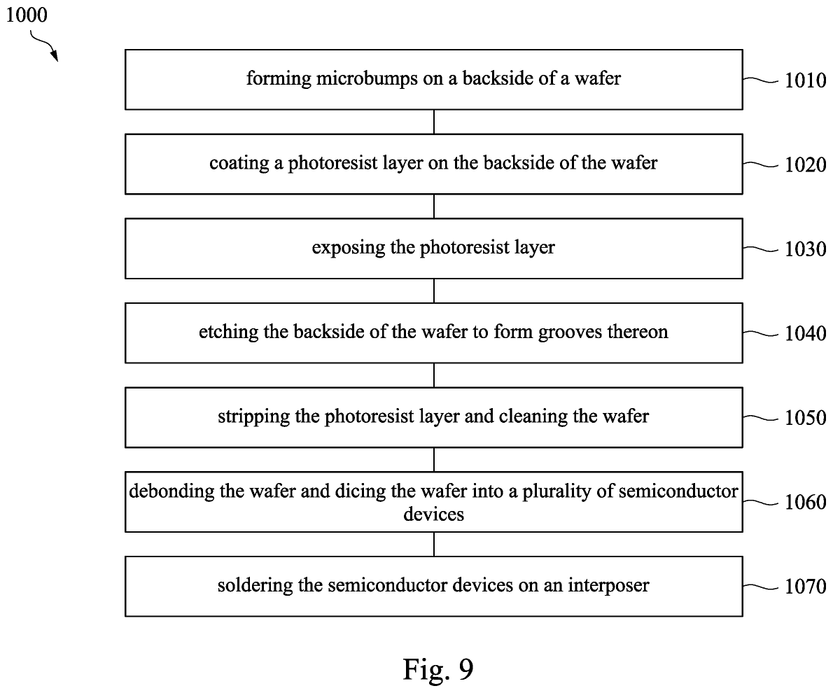

FIGS. 1-7 are cross-sectional views of a three dimensional semiconductor structure manufacturing method at various stages in accordance with some embodiments of the present disclosure, FIG. 8 is a cross-sectional view of a three dimensional semiconductor structure in accordance with another embodiment of the present disclosure and FIG. 9 is a flow chart of a three dimensional semiconductor structure manufacturing method in accordance with some embodiments of the present disclosure.

Referring to FIGS. 1-7 and FIG. 9, a three dimensional semiconductor structure manufacturing method 1000 includes the following steps. In step 1010, a plurality of microbumps are formed on the back side 201 of the wafer 200, as shown in FIG. 1 and FIG. 9. In FIG. 1, a wafer 200 is first provided, and the wafer 200 includes a front side 203 and a back side 201. Then, the front side 203 of the wafer 200 is adhered to a supporting substrate 100 with an adhering layer 210. In addition, a plurality of second microbumps 290 are formed on the back side 201 of the wafer 200.

In addition, the wafer 200 includes a first dielectric layer 220, a first semiconductor layer 230, a second dielectric layer 240, a plurality of metal conductive connections 202, a plurality of first microbumps 250 and a plurality of second microbumps 290. Furthermore, the first semiconductor layer 230 is formed on the first dielectric layer 220, the second dielectric layer 240 is formed on the first semiconductor layer 230, and the metal conductive connections 202 are formed in the first dielectric layer 220, the first semiconductor layer 230 and the second dielectric layer 240. The first microbumps 250 are formed on a surface of the first dielectric layer 220, i.e. the front side 203 of the wafer 200, and the first microbumps 250 are electrically connected to the metal conductive connections 202. The second microbumps 290 are formed on a surface of the second dielectric layer 240, i.e. the back side 201 of the wafer 200, and the second microbumps 290 are electrically connected to the metal conductive connections 202. In addition, a plurality of semiconductor components 300 are formed on the first semiconductor layer 230 and located in the first dielectric layer 220.

In some embodiments, a metal conductive connection 202 includes a first metal pad 260 and a first metal via 270 connected to the first metal pad 260. A first microbump 250 is formed on the first metal pad 260. In addition, the metal conductive connection 202 further includes a second metal via 280, and the second microbump 290 is formed on the second metal via 280 exposed from the second dielectric layer 240 to electrically connect to the metal conductive connection 202 and the first microbump 250.

In some embodiments, the first dielectric layer 220 and the second dielectric layer 240 may include or be formed from at least one of a dielectric material, e.g. a semiconductor carbide (e.g. silicon carbide (SiC)), a semiconductor oxide (e.g. silicon oxide (SiO₂)), a semiconductor nitride (e.g. silicon nitride (SiN)) and a semiconductor oxycarbide (e.g. silicon oxycarbide (SiOC)), but not limited thereto.

In some embodiments, the metal conductive connections 202, for example, the first metal pads 260, the first metal vias 270 and/or the second metal vias 280 can be made from Copper (Cu) and Cu alloys. Copper (Cu) and Cu alloys are used for replacing aluminum (Al) and Al alloys in interconnect metallizations. Cu is relatively inexpensive, easy to process, and has a lower resistivity than Al. In addition, Cu has improved electrical properties vis-a-vis tungsten (W), making Cu a desirable metal for use as a conductive plug as well as conductive wiring. As used herein, “Cu” is intended to encompass high purity elemental copper as well as Cu-based alloys, such as Cu alloys containing minor amounts of tin, zinc, manganese, titanium, magnesium and germanium, but not limited thereto.

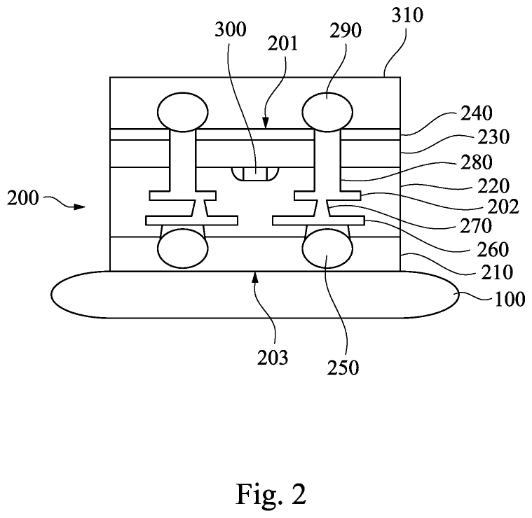

In step 1020, simultaneously referring to FIG. 2 and FIG. 9, a photoresist layer 310 is coated on the back side 201 of the wafer 200.

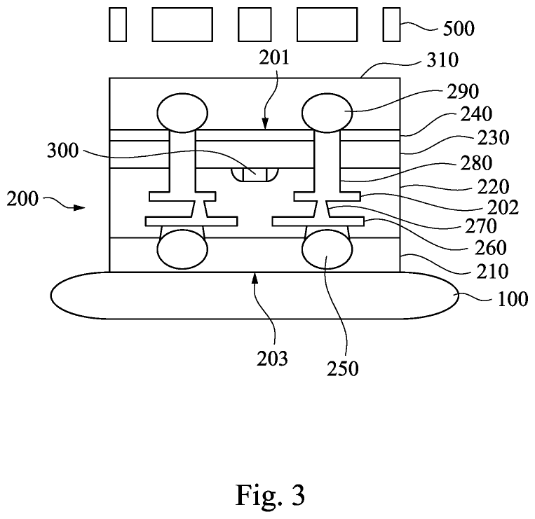

In step 1030, simultaneously referring to FIG. 3 and FIG. 9, a photomask 500 is provided to expose and pattern the photoresist layer 310.

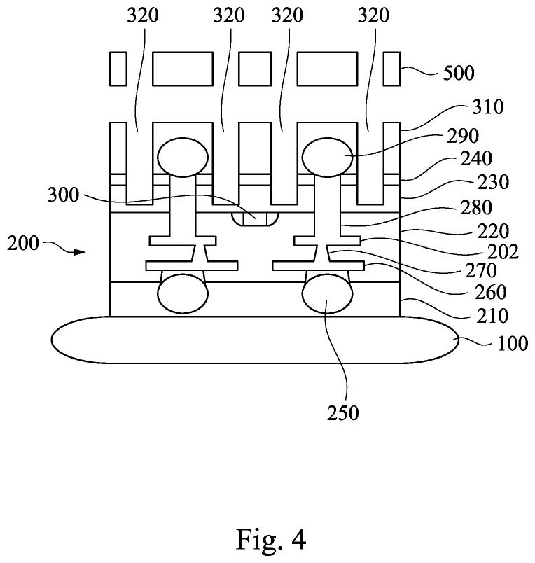

In step 1040, simultaneously referring to FIG. 4 and FIG. 9, the back side 201 of the wafer 200 is etched to form a plurality of grooves 320 on the back side 201 of the wafer 200 so as to form cooling grooves thereon, increase the porosity of the wafer 200, allow airflow to circulate therein and increase heat dissipation efficiency thereof.

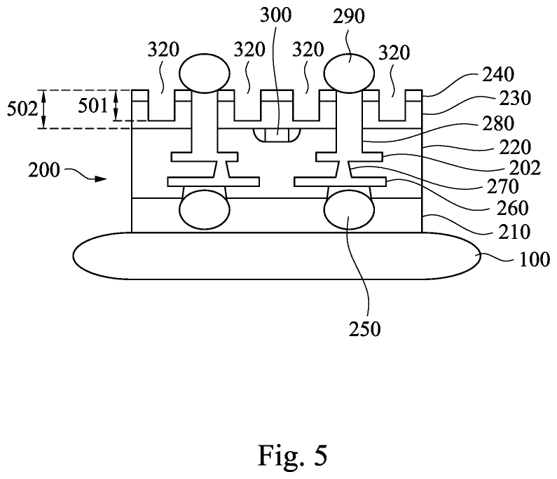

In step 1050, simultaneously referring to FIG. 5 and FIG. 9, the photoresist layer 310 is stripped and cleaned to expose the grooves 320 of the wafer 200 so as to increase the porosity of the wafer 200, allow airflow to circulate therein and increase heat dissipation efficiency thereof.

In some embodiments, the cooling grooves formed by the grooves 320 are preferably formed horizontally on the back side 201 of the wafer 200.

In some embodiments, the grooves 320 are preferably formed by etching through the second dielectric layer 240, and more preferably formed by etching into the first semiconductor layer 230. In addition, a groove depth 501 of the groove 320 is preferably greater than the thickness of the second dielectric layer 240, and more preferably greater than a half of the thickness of the second dielectric layer 240 plus the first semiconductor layer 230. In some embodiments, the groove depth 501 of the groove 320 is approximately equal to ⅔ of the thickness 502 of the second dielectric layer 240 plus the first semiconductor layer 230.

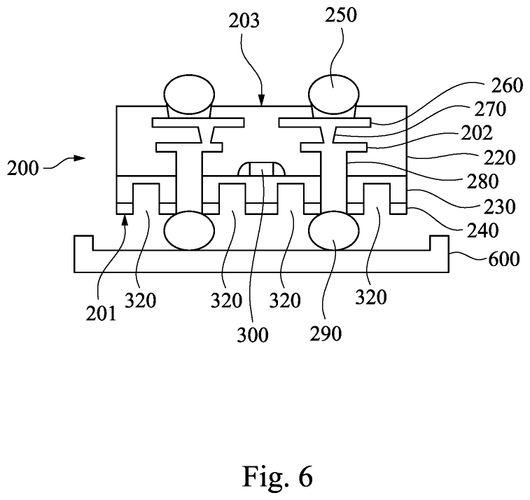

In step 1060, simultaneously referring to FIG. 6 and FIG. 9, the wafer 200 is disposed on a dicing frame 600 and is diced to form a plurality of semiconductor devices 700.

In some embodiments, the cooling grooves formed by the grooves 320 preferably pass horizontally through the semiconductor devices 700.

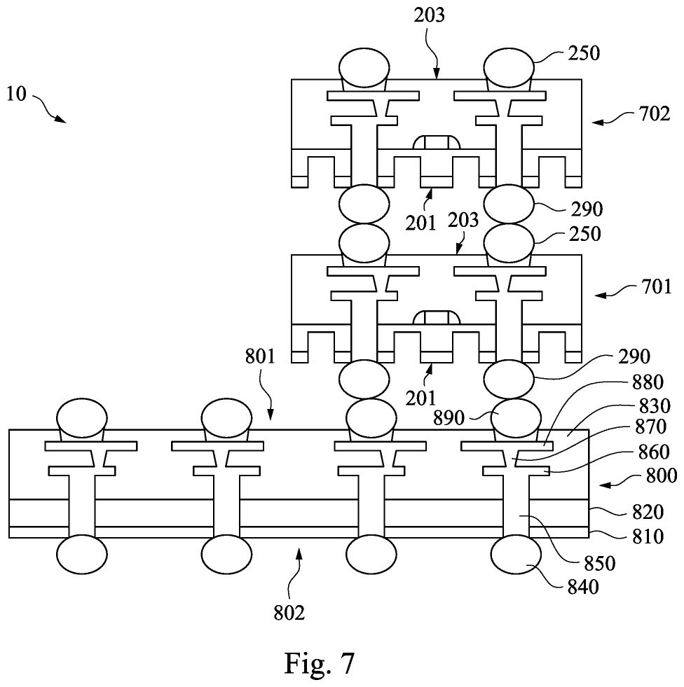

In step 1070, simultaneously referring to FIG. 7 and FIG. 9, the three dimensional semiconductor structure manufacturing method 1000 further includes a step of soldering a first semiconductor device 701 of the semiconductor devices 700 on an interposer 800, and the grooves 320 face the interposer 800.

In some embodiments, the three dimensional semiconductor structure manufacturing method 1000 further includes a step of soldering a second semiconductor device 702 on the first semiconductor device 701, and the cooling grooves of the second semiconductor device 702 face the first semiconductor device 701.

In some embodiments, the interposer 800 includes a third dielectric layer 810, a second semiconductor layer 820, a fourth dielectric layer 830, a plurality of third microbumps 840, a plurality of fourth microbumps 890 and a plurality of metal conductive connections 860.

The second semiconductor layer 820 is formed on the third dielectric layer 810, and the fourth dielectric layer 830 is formed on the second semiconductor layer 820.

In some embodiments, third microbumps 840 are formed on the back side 802 of the interposer 800, i.e. a surface of the third dielectric layer 810, and fourth microbumps 890 are formed on the front side 801 of the interposer 800, i.e. a surface of the fourth dielectric layer 830. In addition, the third microbumps 840 are electrically connected to the metal conductive connections 860, and the fourth microbumps 890 are electrically connected to the metal conductive connections 860.

In some embodiments, the metal conductive connections 860 further include fourth metal vias 850, third metal vias 870 and second metal pads 880. The third microbumps 840 are connected to the fourth metal vias 850, and the fourth microbumps 890 are connected to the second metal pads 880.

The second microbumps 290 of the first semiconductor device 701 are soldered to the fourth microbumps 890 of the interposer 800 to electrically connect the first semiconductor device 701 to the interposer 800.

In some embodiments, the three dimensional semiconductor structure 10 includes a plurality of semiconductor devices 700 stacked together, for example, the first semiconductor device 701 and the second semiconductor device 702 stacked on the first semiconductor device 701, and the first semiconductor device 701 is fixed on the interposer 800 so that the first semiconductor device 701 and the second semiconductor device 702 are electrically connected to the interposer 800.

In some embodiments, the first semiconductor layer 230 and/or the second semiconductor layer 820 includes an elementary semiconductor, such as germanium, or silicon; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Hence, the three dimensional semiconductor structure 10 may use the grooves 320 to form cooling grooves to increase the porosity of the wafer 200, allow airflow to circulate therein and increase the heat dissipation efficiency while the semiconductor devices 700 are working.

In addition, referring to FIG. 8, as shown in the drawing, in some embodiments, the three dimensional semiconductor structure 20 also includes a plurality of semiconductor devices 700 stacked together, for example, the first semiconductor device 701 and the second semiconductor device 702 stacked on the first semiconductor device 701, and the first semiconductor device 701 is fixed on the interposer 900 so that the first semiconductor device 701 and the second semiconductor device 702 are electrically connected to the interposer 900.

In some embodiments, the interposer 900 includes a fifth dielectric layer 910, a third semiconductor layer 920, a sixth dielectric layer 930, a plurality of fifth microbumps 940, a plurality of sixth microbumps 990 and a plurality of metal conductive connections 960.

The third semiconductor layer 920 is formed on the fifth dielectric layer 910, and the sixth dielectric layer 930 is formed on the third semiconductor layer 920.

In some embodiments, fifth microbumps 940 are formed on the back side 902 of the interposer 900, i.e. a surface of the fifth dielectric layer 910, and sixth microbumps 990 are formed on the front side 901 of the interposer 900, i.e. a surface of the sixth dielectric layer 930. In addition, the fifth microbumps 940 are electrically connected to the metal conductive connections 960, and the sixth microbumps 990 are electrically connected to the metal conductive connections 960.

In some embodiments, the metal conductive connections 960 further include sixth metal vias 950, fifth metal vias 970 and third metal pads 980. The fifth microbumps 940 are connected to the sixth metal vias 950, and the sixth microbumps 990 are connected to the third metal pads 980.

The second microbumps 290 of the first semiconductor device 701 are soldered to the sixth microbumps 990 of the interposer 900 to electrically connect the first semiconductor device 701 to the interposer 900.

In some embodiments, the interposer 900 includes a front side 901 and a back side 902, and the first semiconductor device 701 is soldered on the front side 901 of the interposer 800, and the front side 901 of the interposer 900 further includes a plurality of grooves 410 so as to form cooling grooves facing the first semiconductor device 701.

In some embodiments, the grooves 410 of the interposer 900 preferably pass horizontally through the interposer 900.

In some embodiments, the back side 902 of the interposer 900 may also include a plurality of grooves 420 to form cooling grooves opposite to the first semiconductor device 701.

In some embodiments, the grooves 420 of the interposer 900 preferably pass horizontally through the interposer 900.

In some embodiments, the grooves 420 of the interposer 900 are perpendicular to the grooves 410 of the interposer 900.

In some embodiments, the grooves 420 of the interposer 900 are parallel to the grooves 410 of the interposer 900.

Hence, the three dimensional semiconductor structure 20 may use the grooves 320 to form cooling grooves to increase the porosity of the wafer 200, allow airflow to circulate therein and increase the heat dissipation efficiency while the semiconductor devices 700 are working. In addition, the cooling grooves may also be formed on the front side 901 and/or the back side 902 of the interposer 900 to increase the heat dissipation efficiency of the semiconductor devices 700 and the interposer 900.

In some embodiments, the grooves 420 are preferably formed by etching through the fifth dielectric layer 910, and more preferably formed by etching into the third semiconductor layer 920, and the groove depth 503 of the grooves 420 is preferably greater than the thickness of the fifth dielectric layer 910, and more preferably greater than a half of the thickness 504 of the fifth dielectric layer 910 plus the third semiconductor layer 920. In some embodiments, the groove depth 503 of the grooves 420 is approximately equal to ⅔ of the thickness 504 of the fifth dielectric layer 910 plus the third semiconductor layer 920.

In some embodiments, the grooves 410 are preferably formed by etching a portion of the sixth dielectric layer 930, and the groove depth 505 of the grooves 410 is preferably greater than a half of the thickness 506 of the sixth dielectric layer 930. In some embodiments, the groove depth 505 of the grooves 410 is approximately equal to ⅔ of the thickness 506 of the sixth dielectric layer 930.

In some embodiments, the metal conductive connections may be made from Copper (Cu) and Cu alloys. Copper (Cu) and Cu alloys are used for replacing aluminum (Al) and Al alloys in interconnect metallizations. Cu is relatively inexpensive, easy to process, and has a lower resistivity than Al. In addition, Cu has improved electrical properties vis-a-vis tungsten (W), making Cu a desirable metal for use as a conductive plug as well as conductive wiring. As used herein, “Cu” is intended to encompass high purity elemental copper as well as Cu-based alloys, such as Cu alloys containing minor amounts of tin, zinc, manganese, titanium, magnesium and germanium, but not limited thereto.

In some embodiments, the dielectric layer may include or be formed from at least one of a dielectric material, e.g. a semiconductor carbide (e.g. silicon carbide (SiC)), a semiconductor oxide (e.g. silicon oxide (SiO₂)), a semiconductor nitride (e.g. silicon nitride (SiN)) and a semiconductor oxycarbide (e.g. silicon oxycarbide (SiOC)), but not limited thereto.

Accordingly, the three dimensional semiconductor structure of the present invention includes the grooves formed on the surface of the semiconductor devices to form the cooling grooves so as to increase the porosity of the wafer, allow airflow to circulate therein and increase the heat dissipation efficiency while the semiconductor devices are working. In addition, the cooling grooves may also be formed on the front side and/or the back side of the interposer to increase the heat dissipation efficiency of the semiconductor devices and the interposer.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A three dimensional semiconductor structure manufacturing method, comprising:
providing a wafer, wherein the wafer comprises a front side and a back side;
adhering the front side of the wafer on a supporting substrate;
coating a photoresist layer on the back side of the wafer;
etching the back side of the wafer to form a plurality of grooves on the back side of the wafer; and
dicing the wafer to form a plurality of semiconductor devices.

2. The three dimensional semiconductor structure manufacturing method of claim 1, wherein each of the semiconductor devices comprises a plurality of cooling grooves formed by the grooves on the back side of the wafer.

3. The three dimensional semiconductor structure manufacturing method of claim 2, wherein the cooling grooves pass horizontally through the semiconductor devices.

4. The three dimensional semiconductor structure manufacturing method of claim 3, further comprising:
soldering a first semiconductor device of the semiconductor devices on an interposer, wherein the cooling grooves face the interposer.

5. The three dimensional semiconductor structure manufacturing method of claim 4, further comprising:
soldering a second semiconductor device on the first semiconductor device, wherein cooling grooves of the second semiconductor device face the first semiconductor device.

6. The three dimensional semiconductor structure manufacturing method of claim 4, wherein the interposer comprises a front side and a back side, and the first semiconductor device is soldered on the front side of the interposer.

7. The three dimensional semiconductor structure manufacturing method of claim 6, wherein the front side of the interposer comprises a plurality of grooves facing the first semiconductor device.

8. The three dimensional semiconductor structure manufacturing method of claim 7, wherein the grooves of the front side of the interposer pass horizontally through the interposer.

9. The three dimensional semiconductor structure manufacturing method of claim 6, wherein the back side of the interposer comprises a plurality of grooves.

10. The three dimensional semiconductor structure manufacturing method of claim 6, wherein the grooves of the back side of the interposer pass horizontally through the interposer.

11. A three dimensional semiconductor structure, comprising:
a first semiconductor device comprising a front side and a back side; and
a plurality of grooves formed on the back side of the first semiconductor device to form a plurality of cooling grooves.

12. The three dimensional semiconductor structure of claim 11, wherein the cooling grooves pass horizontally through the first semiconductor device.

13. The three dimensional semiconductor structure of claim 11, further comprising:
an interposer, wherein the first semiconductor device is soldered on the interposer and the cooling grooves face the interposer.

14. The three dimensional semiconductor structure of claim 13, further comprising:
a second semiconductor device soldering on the first semiconductor device, wherein cooling grooves of the second semiconductor device face the first semiconductor device.

15. The three dimensional semiconductor structure of claim 13, wherein the interposer comprises a front side and a back side, and the first semiconductor device is soldered on the front side of the interposer.

16. The three dimensional semiconductor structure of claim 15, wherein the front side of the interposer comprises a plurality of grooves facing the first semiconductor device.

17. The three dimensional semiconductor structure of claim 16, wherein the grooves of the front side of the interposer pass horizontally through the interposer.

18. The three dimensional semiconductor structure of claim 15, wherein the back side of the interposer comprises a plurality of grooves.

19. The three dimensional semiconductor structure of claim 18, wherein the grooves of the back side of the interposer pass horizontally through the interposer.

20. The three dimensional semiconductor structure of claim 11, wherein the first semiconductor device comprises:
a first dielectric layer;
a first semiconductor layer formed on the first dielectric layer;
a second dielectric layer formed on the first semiconductor layer;
a plurality of metal conductive connections formed in the first dielectric layer, the first semiconductor layer and the second dielectric layer;
a plurality of first microbumps formed on a surface of the first dielectric layer and electrically connecting to the metal conductive connections; and
a plurality of second microbumps formed on a surface of the second dielectric layer and electrically connecting to the metal conductive connections.
